(19) United States
(12) Patent Application Publication
(10) Pub. No.: US 2025/0022710 A1
(43) Pub. Date: Jan. 16, 2025

(54) SEMICONDUCTOR DEVICE AND METHOD OF MANUFACTURING SEMICONDUCTOR DEVICE

(71) Applicant: FUJI ELECTRIC CO., LTD., Kanagawa (JP)

(72) Inventor: Soichi YOSHIDA, Matsumoto-city (JP)

(21) Appl. No.: 18/896,890

(22) Filed: Sep. 26, 2024

Related U.S. Application Data
(63) Continuation of application No. PCT/JP2023/030566, filed on Aug. 24, 2023.

(30) Foreign Application Priority Data
Oct. 13, 2022 (JP) 2022-164444

(51) Int. Cl. H01L 21/22; H01L 23/29; H01L 23/31; H01L 27/06; H01L 29/06; H01L 29/32; H01L 29/66; H01L 29/739; H01L 29/861

(52) U.S. Cl. CPC H01L 21/221; H01L 23/293; H01L 23/3171; H01L 27/0664; H01L 29/0696; H01L 29/32; H01L 29/66348; H01L 29/7397; H01L 29/8613

(57) ABSTRACT

Provided is a semiconductor device including: a semiconductor substrate including an active portion in which transistor portions and diode portions are alternately provided and provided with a plurality of trench portions extending in an extending direction of the transistor portion and the diode portion; an emitter electrode provided above a front surface of the semiconductor substrate; and a protective film of polyimide provided on an upper surface of the emitter electrode, wherein the diode portion includes a lifetime control region including a lifetime killer irradiated from a front surface side of the semiconductor substrate, wherein the active portion includes a protected region provided with the protective film and an unprotected region not provided with the protective film, and wherein the diode portion is included in the unprotected region and the protected region is included in the transistor portion.

The contents of the following patent application(s) are incorporated herein by reference:
NO. 2022-164444 filed in JP on Oct. 13, 2022
NO. PCT/JP2023/030566 filed in WO on Aug. 24, 2023

### BACKGROUND

### 1. Technical Field

The present invention relates to a semiconductor device and a method of fabricating a semiconductor device.

### 2. Related Art

Conventionally, a technique of providing a lifetime control region including a lifetime killer by irradiating a particle line such as a helium ion into a predetermined depth position of a semiconductor substrate in a semiconductor device in which a transistor portion such as an insulated gate bipolar transistor (IGBT) and a diode portion are formed in the same substrate is known (for example, Patent Document 1.)

In addition, a semiconductor device provided with a protective film formed of polyimide resin formed as a cross shaped pattern on a surface of a device electrode formed of an aluminum thin film is disclosed (for example, Patent Document 2.)

### PRIOR ART DOCUMENT

### Patent Document

Patent Document 1: Japanese Patent Application Publication No. 2017-135339
Patent Document 2: Japanese Patent Application Publication No. 2009-38140

### BRIEF DESCRIPTION OF THE DRAWINGS

FIG. 1 illustrates an example of an arrangement of each component on a front surface of a semiconductor device 100 according to the example.

FIG. 2 illustrates an example of an arrangement of an emitter electrode 52 provided on a front surface of the semiconductor device 100.

FIG. 3 illustrates an example of an arrangement of a protective film 150 provided on a front surface of the semiconductor device 100.

FIG. 4 illustrates an example of an a-a′ cross section of FIG. 3.

FIG. 5 illustrates an example of a top plan view of the semiconductor device 100.

FIG. 6 schematically illustrates a structure of a front surface of the semiconductor substrate 10 in the vicinity of the protected region 151-1.

FIG. 7 illustrates an example of a b-b′ cross section of FIG. 6.

FIG. 8 illustrates an example of a method of fabricating the semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

Herein, one side of a semiconductor substrate in a direction parallel to a depth direction of the semiconductor substrate is referred to as “front” or “upper”, and the opposite side is referred to as “back” or “lower”. One surface of two principal surfaces of a substrate, a layer or other member is referred to as an upper surface, and another surface is referred to as a lower surface. The direction indicated by “front”, “upper”, “back”, or “lower” is not limited to the gravitational direction or direction of implementing the semiconductor device.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the −Z axis direction are directions opposite to each other. When the Z axis direction is described without describing the signs, it means that the direction is parallel to the +Z axis and the −Z axis. As used herein, when seen from the +Z axis direction, it may also be referred to as a “top plan view”.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. Note that conductivity types of respective doping regions may be of opposite polarities, respectively. Further, in the present specification, a description of a P+ type or an N+ type means a higher doping concentration than that of the P type or the N type, and a description of a P-type or an N-type means a lower doping concentration than that of the P type or the N type.

In the present specification, the doping concentration indicates a concentration of an impurity activated as a donor or an acceptor. Herein, in some cases, a concentration difference between a donor and an acceptor may be a higher concentration of the two, the donor or the acceptor. The concentration difference can be measured by the capacitance-voltage profiling method (CV method). Also, a carrier concentration measured by Spread Resistance (SR) measurement method may be a concentration of a donor or an acceptor. Furthermore, in a case where a concentration distribution of a donor or an acceptor has a peak, the peak value may be a concentration of a donor or acceptor in the region. In a region where donors or acceptors are present, when concentration of the donors or the acceptors is substantially uniform or the like, an average value of donor concentration or acceptor concentration in this region may be set as donor concentration or acceptor concentration.

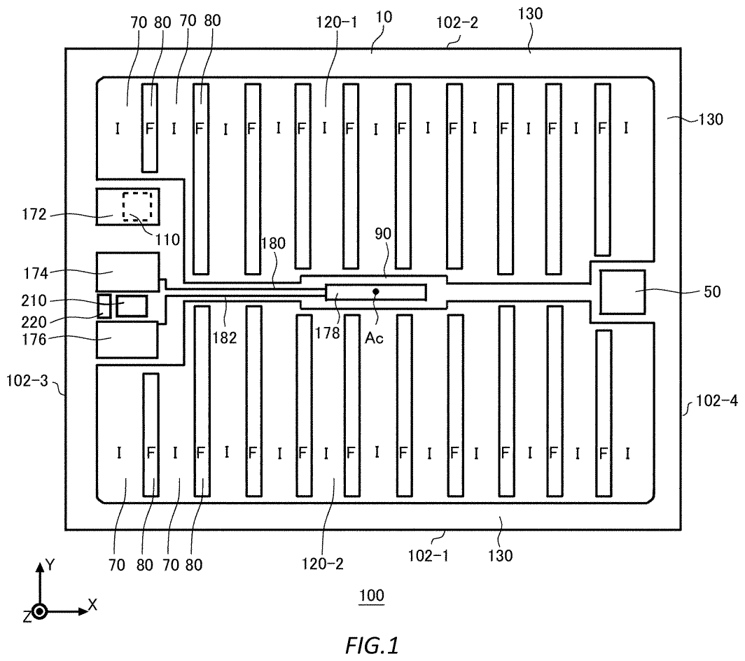

FIG. 1 illustrates an example of an arrangement of each component on a front surface of a semiconductor device 100 according to the example. The semiconductor device 100 includes a semiconductor substrate 10, a gate pad 50, a current sensing pad 172, a temperature sensing portion 178, an anode pad 174 and a cathode pad 176 electrically connected to the temperature sensing portion 178, a bidirectional diode portion 210, and an output comparison diode portion 220. A region in which the current sensing pad 172, the anode pad 174, the cathode pad 176, the bidirectional diode portion 210 and the output comparison diode portion 220 are provided may be collectively referred to as a pad region.

The semiconductor substrate 10 has an end side 102. As used herein, in a top plan view of FIG. 1, a direction along one end side 102-1 of the semiconductor substrate 10 is considered to be an X axis direction, and a direction perpendicular to the X axis direction is considered to be a Y axis direction. In the present example, the X axis is taken in a direction along the end side 102-1. A direction being perpendicular to the X axis direction and the Y axis direction, and forming a right-hand system with the X axis direction and the Y axis direction is referred to as a Z axis direction. The temperature sensing portion 178 of the present example is provided in the +Z axis direction of the semiconductor substrate 10.

The semiconductor substrate 10 is provided of semiconductor materials such as silicon or a compound semiconductor. A side of the semiconductor substrate 10 on which the temperature sensing portion 178 is provided is referred to as a front surface, and the opposing side is referred to as a back surface. As used herein, a direction connecting the front surface and the back surface of the semiconductor substrate 10 is referred to as a depth direction. Although the semiconductor substrate 10 of the present example has a substantially rectangular shape on the front surface, the semiconductor substrate 10 may be in a different shape.

The semiconductor substrate 10 includes an active portion 120. The active portion 120 is a region in which main current flows in the depth direction between the front surface and the back surface of the semiconductor substrate 10 when the semiconductor device 100 is turned on. A gate conductive portion 44 of the active portion 120 described below is electrically connected to a gate pad 50 by a gate runner portion described below.

The active portion 120 may be arranged to be divided into an active portion 120-1 and an active portion 120-2 in a top plan view. The active portion 120-1 and the active portion 120-2 of the present example are separated in the Y axis direction by a separation portion 90 extending the Y axis direction through a center Ac of a front surface of the semiconductor substrate 10. Here, the center Ac of the active portion 120 is a geometric center of gravity of the active portion 120 in a top plan view. The active portion 120-1 and the active portion 120-2 may be provided such that a pad region is interpose therebetween.

The active portion 120 is provided with a transistor portion 70 including a transistor device such as an IGBT (insulated gate bipolar transistor) and a diode portion 80 including a diode device such as an FWD (free wheeling diode.)

The transistor portion 70 and the diode portion 80 form an RC-IGBT (Reverse Conducting IGBT.)

In FIG. 1, in the active portion 120, a region in which the transistor portion 70 is arranged is provided with a symbol “I” and a region in which the diode portion 80 is arranged is provided with a symbol “F”. The transistor portions 70 and the diode portions 80 of the present example are alternately arranged side by side in the X axis direction in each region of the active portion 120. In the X axis direction, a width of the transistor portion 70 is equal to or greater than 300 μm and equal to or smaller than 2000 μm, and a width of the diode portion 80 is equal to or greater than 200 μm and equal to or smaller than 2000 μm.

The semiconductor device 100 includes, on a front surface, an edge termination structure portion between an outer circumference of the active portion 120 and the end side 102. The edge termination structure portion includes, for example, a guard ring that is annularly provided so as to surround the active portion 120, or a field plate, and a combination thereof.

The temperature sensing portion 178 may be arranged in the separation portion 90. The separation portion 90 is not provided with the active portion 120. When the active portions 120 of the semiconductor substrate 10 are integrated, the center portion of the semiconductor substrate 10 is easily heated by heat generated from switching devices which are formed in the active portions 120. The temperature sensing portion 178 is provided in the separation portion 90 in the vicinity of the center such that a temperature of the transistor portion 70 can be monitored. This can prevent the transistor portion 70 from overheating beyond a junction temperature that is a normal operating temperature range.

The temperature sensing portion 178 may be provided of a temperature sensing diode. As an example, the temperature sensing portion 178 is provided of a Schottky diode. In addition, the temperature sensing portion 178 may be provided of P-N junction diodes of polysilicon provided via an insulating film above the semiconductor substrate 10.

A anode wiring 180 and a cathode wiring 182 formed of metal are connected to an anode and cathode of the temperature sensing diode, respectively. The anode wiring 180 and the cathode wiring 182 contain metal such as aluminum. The anode wiring 180 and the cathode wiring 182 are an example of a temperature sensing wiring. The anode wiring 180 and the cathode wiring 182 are provided to extend in the separation portion 90.

The cathode pad 176 is connected to the temperature sensing portion 178 via the cathode wiring 182. The anode pad 174 is connected to the temperature sensing portion 178 via the anode wiring 180. The cathode pad 176 and the anode pad 174 are electrodes containing metal such as aluminum.

The current sensing pad 172 is electrically connected to a current sensing portion 110. The current sensing pad 172 is an example of the front surface electrode. The current sensing portion 110 has a structure similar to the structure of the transistor portion 70 in the active portion 120, and simulates operations of the transistor portion 70. Current that flows into the current sensing portion 110 is in proportion to current that flows into the transistor portion 70. This can allow a current flowing through the transistor portion 70 to be monitored.

Note that the current sensing portion 110 is not provided with an emitter region 12 described below, unlike the transistor portion 70. That is, the current sensing portion 110 does not operate as a transistor. The current sensing portion 110 is provided with a gate trench portion. The gate trench portion of the current sensing portion 110 is electrically connected to the gate runner portion.

The bidirectional diode portion 210 is arranged between the anode pad 174 and the cathode pad 176 on a front surface of the semiconductor device 100. The bidirectional diode portion 210 includes a diode electrically connected in a serial bidirectional way between the anode pad 174 and the cathode pad 176. The bidirectional diode portion 210 prevents the temperature sensing portion 178 from being damaged by electro-static discharge (ESD).

The output comparison diode portion 220 is provided between the anode pad 174 and the cathode pad 176. The output comparison diode portion 220 is electrically connected to the anode pad 174 and the cathode pad 176. The output comparison diode portion 220 includes an output comparison diode with P-N junctions connected in inverse-parallel to the direction of the P-N junctions of the temperature sensing diodes of the temperature sensing portion 178.

The output comparison diodes of the output comparison diode portion 220 may have the design similar to that of the diodes of the temperature sensing portion 178, except for the direction of the P-N junctions. During operation of the semiconductor device 100, a current does not flow through the output comparison diode portion 220. An output comparison operation is performed for each predetermined cycle. At a time of the output comparison operation, the current flows through the output comparison diode portion 220. The output comparison operation can notify when the temperature sensing diodes of the temperature sensing portion 178 should be replaced.

In parallel to the output comparison diode portion 220, a protective diode may be provided of which the forward direction is the same as that of the output comparison diode portion 220. The protective diode prevents noises and so on from causing an overvoltage applied to or an overcurrent flowing into the temperature sensing portion 178 during operation of the temperature sensing portion 178.

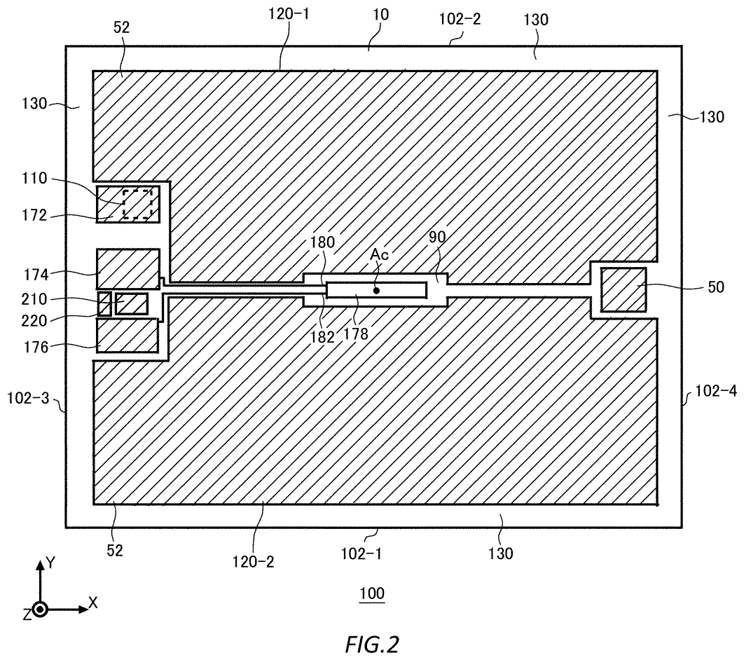

FIG. 2 illustrates an example of an arrangement of an emitter electrode 52 provided on a front surface of the semiconductor device 100. The emitter electrode 52 is provided of a conductor of a metal such as aluminum. The emitter electrode 52 of the present example is set at an emitter potential which is a predetermined reference potential. Alternatively, the emitter potential may be set to be a ground potential.

The emitter electrode 52 is formed of a conductive material including a metal. For example, the emitter electrode 52 is formed of aluminum or an alloy containing aluminum as a main component (such as an aluminum-silicon or aluminum-silicon-copper alloy). The emitter electrode 52 is an example of a front surface electrode, similarly to the current sensing pad 172. Each electrode may have, in an underlying layer of the region formed of aluminum or the like, a barrier metal which is formed of titanium, titanium compounds, or the like.

In FIG. 2, the emitter electrode 52 is arranged in a region hatched with diagonal lines. The emitter electrode 52 is not provided above the separation portion 90 which separates the active portion 120-1 and the active portion 120-2 from each other in the Y axis direction. Similarly, the emitter electrode 52 is not provided above the pad region.

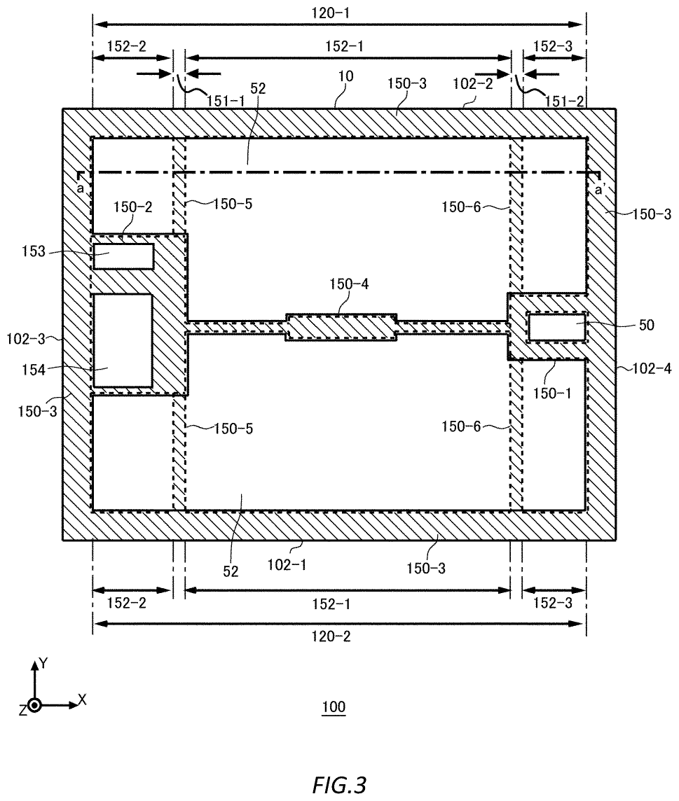

FIG. 3 illustrates an example of an arrangement of the protective film 150 provided above the front surface of the semiconductor device 100. The protective film 150 of the present example is formed of polyimide. In FIG. 3, a region in which the protective film 150 is s arranged has a contour indicated by a dashed line and is hatched with diagonal lines. The protective film 150 may be in contact with an upper surface of the emitter electrode 52.

The protective film 150 of the present example includes a protective film 150-1 which covers a region in which the gate pad 50 is provided and a protective film 150-2 which covers the pad region. The protective film 150-1 may include an opening which exposes a part of an upper surface of the gate pad 50. Further, the protective film 150-1 may include an opening 153 which exposes a part of an upper surface of the current sensing pad 172 and an opening 154 which exposes a part of upper surfaces of the anode pad 174 and the cathode pad 176. In this way, a wire or the like can be connected to the upper surface of the gate pad 50. In addition, similarly, a wire or the like can be connected to upper surfaces of the current sensing pad 172, the anode pad 174 and the cathode pad 176.

The protective film 150 may further include a protective film 150-3 provided between an outer circumference of the active portion 120 and the end side 102 (end sides 102-1 to 102-4) and a protective film 150-4 which covers the separation portion 90. That is, the emitter electrode 52 is divided into two regions surrounded by the protective film 150-1, the protective film 150-2, the protective film 150-3 and the protective film 150-4.

The protective film 150 of the present example further includes a protective film 150-5 and a protective film 150-6 provided to extend on an upper surface of the emitter electrode 52 in the Y axis direction. In FIG. 3, in the Y axis direction, the protective film 150-5 is interposed between the protective film 150-2 and the protective film 150-3, and the protective film 150-6 is interposed between the protective film 150-1 and the protective film 150-3.

The protective film 150-5 and the protective film 150-6 are provided on the upper surface of the emitter electrode 52, unlike other protective films 150 provided on the front surface of the semiconductor substrate 10. That is, in the protective film 150, only the protective film 150-5 and the protective film 150-6 are provided in the active portion 120. The active portion 120 include a protected region 151 provided with a protective film and an unprotected region 152 not provided with a protective film. The active portion 120 of the present example includes a protected region 151-1 and a protected region 151-2 provided with the protective film 150-5 and the protective film 150-6, and an unprotected region 152-1, an unprotected region 152-2 and an unprotected region 152-3 not provided with a protective film.

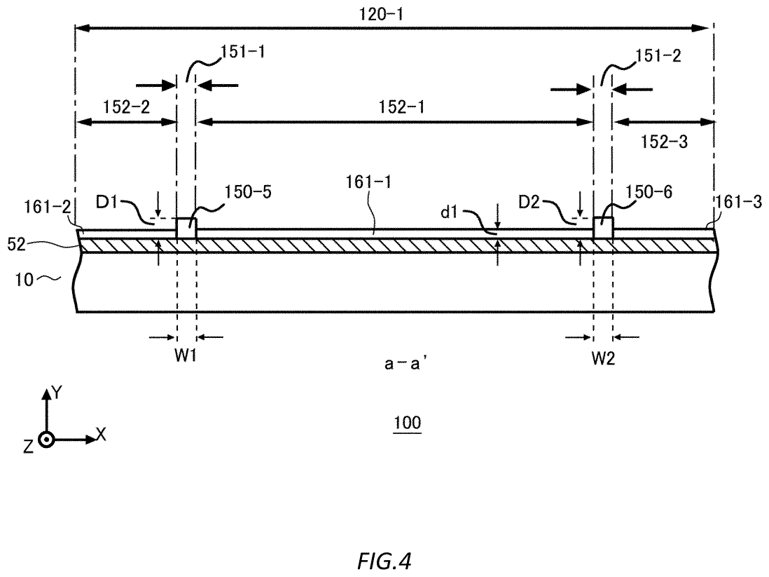

FIG. 4 illustrates an example of an a-a′ cross section of FIG. 3. The a-a′ cross section is an X-Z plane extending through the active portion 120-1. The active portion 120-1 of the present example includes, in a top plan view, the unprotected region 152-1 provided in the vicinity of the center, and the unprotected region 152-2 and the unprotected region 152-3 positioned at both sides of the unprotected region 152-1 in the X axis direction. The active portion 120-1 further includes the protected region 151-1 interposed between the unprotected region 152-1 and the unprotected region 152-2, and the protected region 151-2 interposed between the unprotected region 152-1 and the unprotected region 152-3. The protected region 151-1 and the protected region 151-2 are provided with the protective film 150-5 and the protective film 150-6, respectively.

A plating portion 161 is provided on the upper surface of the emitter electrode 52. As an example, the plating portion 161 is Ni/Au including an Au layer stacked on an Ni layer. The plating portion 161 is separated into a plating portion 161-1, a plating portion 161-2 and a plating portion 161-3 by the protective film 150-5 and the protective film 150-6. The plating portion 161-1, the plating portion 161-2 and the plating portion 161-3 are provided the unprotected region 152-2 and the unprotected region 152-3 positioned at both sides of the unprotected region 152-1, respectively.

In FIG. 4, the protective film 150-5 is interposed between the plating portion 161-1 and the plating portion 161-2, and the protective film 150-6 is interposed between the plating portion 161-1 and the plating portion 161-3. The emitter electrode 52 is provided to extend below the protective film 150-5 and the protective film 150-6, and the plating portion 161-1, the plating portion 161-2 and the plating portion 161-3.

In the X axis direction, a width W1 of the protected region 151-1 may be the same as a width W2 of the protected region 151-2. In the present example, the width W1 of the protected region 151-1 and the width W2 of the protected region 151-2 is equal to or greater than 100 μm and equal to or smaller than 1800 μm.

A thickness D1 of the protective film 150-5 and a thickness D2 of the protective film 150-6 may be the same. Here, the thickness refers to a distance with reference to the upper surface of the emitter electrode 52 in the +Z axis direction. In the present example, the thickness D1 of the protective film 150-5 and the thickness D2 of the protective film 150-6 are greater than a thickness d1 of the plating portion 161-1 interposed between the protective film 150-5 and the protective film 150-6. The thickness D1 of the protective film 150-5 and the thickness D2 of the protective film 150-6 is equal to or greater than 5 μm and equal to or smaller than 15 μm. The thickness d1 of the plating portion 161-1 is equal to or greater than 1 μm and equal to or smaller than 10 μm.

Referring to FIG. 3 again, in a top plan view, an area of the unprotected region 152-1 is greater than each area of the unprotected region 152-2 and the unprotected region 152-3. Therefore, when the semiconductor device 100 is mounted, a wiring such as a lead frame is joined via a solder layer provided on the plating portion 161-1 of the unprotected region 152-1 such that the emitter electrode 52 can easily be electrically connected to the outside.

In addition, heights of the protective film 150-5 and the protective film 150-6 are greater than a height of the plating portion 161-1 such that a solder layer and the like on the plating portion 161-1 of the unprotected region 152-1 can be prevented from being spilled out into the unprotected region 152-2 and the unprotected region 152-3. In addition, the unprotected region 152-2 and the unprotected region 152-3 are provided at the opposite sides of the unprotected region 152-1 such that the solder layer and the like on the front surface of the semiconductor substrate 10 can be prevented from being at imbalanced positions.

FIG. 4 illustrates an X-Z plane extending through the active portion 120-1. An X-Z plane extending through the active portion 120-2 also has the similar configuration and therefore the description is omitted here.

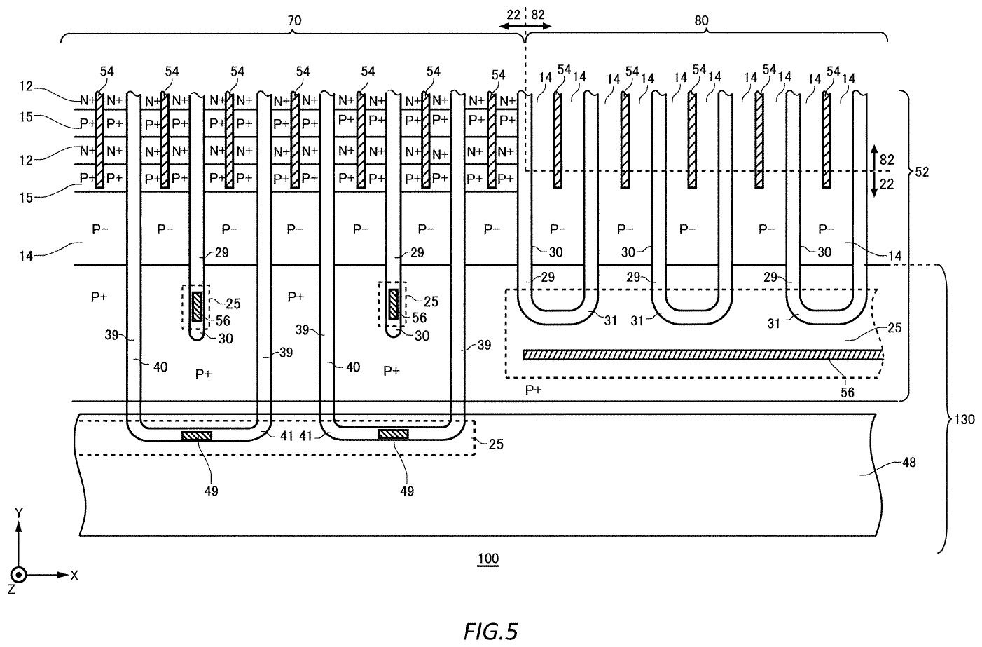

FIG. 5 illustrates an example of a top plan view of the semiconductor device 100. FIG. 5 illustrates the vicinity of an end of the active portion 120-2 in the negative Y axis direction. The semiconductor device 100 is provided with the semiconductor substrate 10 having the transistor portion 70 including a transistor device such as an IGBT and the diode portion 80 including a diode device such as a free wheeling diode (FWD).

The semiconductor device 100 of the present example includes a gate trench portion 40, a dummy trench portion 30, a well region 130, an emitter region 12, a base region 14, and a contact region 15 provided in the front surface side of the semiconductor substrate 10. The gate trench portion 40 and the dummy trench portion 30 each are an example of the trench portion.

In addition, the semiconductor device 100 of the present example includes a gate metal layer 48 and the emitter electrode 52 which are provided above the front surface of the semiconductor substrate 10. The gate metal layer 48 and the emitter electrode 52 are also an example of the front surface electrode. The gate metal layer 48 and the emitter electrode 52 are provided separately from each other. The gate metal layer 48 and the emitter electrode 52 are electrically insulated.

Although an interlayer dielectric film is provided between the emitter electrode 52 and the gate metal layer 48, and the front surface of the semiconductor substrate 10, it is omitted in FIG. 5. In the interlayer dielectric film of the present example, contact holes 49, 54, and 56 are provided to pass through the interlayer dielectric film. In FIG. 5, each contact hole is hatched with the diagonal lines.

The emitter electrode 52 is provided above the gate trench portion 40, the dummy trench portion 30, the well region 130, the emitter region 12, the base region 14, and the contact region 15. The emitter electrode 52 is electrically connected to the emitter region 12, the base region 14 and the contact region 15 on the front surface of the semiconductor substrate 10 through the contact hole 54. In addition, the emitter electrode 52 is connected to a dummy conductive portion in the dummy trench portion 30 through the contact hole 56.

The gate metal layer 48 may be provided in an annular shape along an outer circumference of the active portion 120. The gate metal layer 48 of the present example is provided along outer circumferences of the active portion 120-1 and the active portion 120-2, respectively. The gate metal layer 48 is connected to a gate conductive portion in the gate trench portion 40 through the contact hole 49.

The front surface electrode such as the emitter electrode 52 or the gate metal layer 48 are formed of a conductive material including a metal. For example, they are formed of aluminum or an aluminum-silicon alloy. Each electrode may have a barrier metal formed of titanium, a titanium compound, or the like as an underlying layer of a region formed of aluminum or the like.

Each electrode may have a plug formed of tungsten or the like in the contact hole. The plug may have a barrier metal on a side in contact with the semiconductor substrate 10 and have tungsten embedded to be in contact with the barrier metal, and may be formed of aluminum or the like on tungsten.

It should be noted that the plug is provided in the contact hole in contact with the contact region 15 or the base region 14. In addition, below the contact hole with a plug, a plug region of a P++ type having a doping concentration higher than the contact region 15 may be provided. This can improve a contact resistance between the barrier metal and the contact region 15. In addition, the depth of the plug region is about 0.1 μm or smaller occupying a small region which is equal to or smaller than 10% of the depth of the contact region 15.

The plug region improves the contact resistance to increase a latch-up withstand capacity of the transistor portion 70 during operation. On the other hand, during operation of the diode portion 80, increases in conduction loss and switching loss can be prevented.

A connecting portion 25 may further be provided to electrically connect the front surface electrode such as the emitter electrode 52 or the gate metal layer 48 to the semiconductor substrate 10. In an example, the connecting portion 25 is provided in a region including inside of the contact hole 49 between the gate metal layer 48 and the gate conductive portion. The connecting portion 25 may also be provided in a region that is between the emitter electrode 52 and the dummy conductive portion and that includes an interior of the contact hole 56.

The connecting portion 25 is formed of a conductive material including metal such as tungsten, and polysilicon doped with impurities. In addition, the connecting portion 25 may also include a barrier metal of titanium nitride or the like. Here, the connecting portion 25 is formed of polysilicon (N+) doped with the impurities of the N type. The connecting portion 25 is provided above the front surface of the semiconductor substrate 10 via an insulating film such as an oxidize film.

The well region 130 is provided to be closer to the front surface of the semiconductor substrate 10 than the drift region 18 which will be described below. The well region 130 of the present example is of P+ type. The well region 130 of the present example is provided in the edge termination structure portion and the separation portion 90. In addition, the well region 130 is provided within the predetermined range from the outer circumferences of the active portion 120-1 and the active portion 120-2 to the inside. The well region 130 is electrically connected to the emitter electrode 52. The well region 130 is provided from the front surface of the semiconductor substrate 10 to a position deeper than a lower end of the base region 14.

Each of the transistor portion 70 and the diode portion 80 has a plurality of trench portions arrayed in an array direction. In the transistor portion 70 of the present example, one or more gate trench portions 40 and one or more dummy trench portions 30 are alternately provided along the array direction. In the diode portion 80 in this example, the plurality of dummy trench portions 30 are provided along the array direction.

In the present example, the array direction of the trench portions is the X axis direction, and the extending direction perpendicular to the array direction is the Y axis direction. The gate trench portion 40 of the present example may have two extending portions 39 extending along the extending direction (portions of the trench that are linear along the extending direction), and a connecting portion 41 connecting the two extending portions 39.

At least a part of the connecting portion 41 may be provided in a curved shape in the top plan view. Ends of two extending portions 39 in the Y axis direction are connected to the gate metal layer 48 by the connecting portion 41 to function as a gate electrode for the gate trench portion 40. On the other hand, by forming the connecting portion 41 into the curved shape, an electric field concentration at the end portions can be reduced, in comparison with a case where they end up with the extending portions 39.

In the transistor portion 70, the dummy trench portions 30 are provided between the respective extending portions 39 of the gate trench portion 40. In the example of FIG. 4, one dummy trench portion 30 is provided between the respective extending portions 39. However, two or more dummy trench portions 30 may be provided.

In addition, between the respective extending portions 39, the dummy trench portion 30 may not be provided, and the gate trench portion 40 may be provided. With such a structure, the electron current from the emitter region 12 can be increased, so that an ON voltage is reduced.

The dummy trench portion 30 may have a straight shape extending in the extending direction, and may have an extending portion 29 and a connecting portion 31, similarly to the gate trench portion 40. In the semiconductor device 100 shown in FIG. 4, only the dummy trench portions 30 including the connecting portions 31 are arrayed. In another example, however, the semiconductor device 100 may include the dummy trench portion 30 of a straight shape not including the connecting portion 31.

A diffusion depth of the well region 130 may be deeper than the depths of the gate trench portion 40 and the dummy trench portion 30. End portions of the gate trench portion 40 and the dummy trench portion 30 in the Y axis direction are provided in the well region 130 in the top plan view. That is, at the end portion of each trench portion in the Y axis direction, a bottom portion of each trench portion in the depth direction (−Z axis direction) is covered with the well region 130. With this configuration, the electric field concentration on the bottom portion of each trench portion can be reduced.

A mesa portion is provided between the respective trench portions in the array direction. The mesa portion refers to a region sandwiched between the trench portions inside the semiconductor substrate 10. As an example, a depth position of the mesa portion is from the front surface of the semiconductor substrate to a lower end of the trench portion.

The mesa portion of the present example is interposed between the trench portions adjacent in the X axis direction, and is provided to extend in the extending direction (Y axis direction) along the trench in the front surface of the semiconductor substrate 10.

Each mesa portion is provided with the base region 14. Each mesa portion may be provided with, in a top plan view, at least one of the emitter region 12 and the contact region 15 in a region interposed between the base regions 14. In the present example, the base region 14 is of a P-type, the emitter region 12 is of an N+ type, and the contact region 15 is of a P+ type. The base region 14 may be provided in contact with the well region 130. The emitter region 12 and the contact region 15 may be provided between the base region 14 and the front surface of the semiconductor substrate 10 in the depth direction. Examples of the dopant of the emitter region 12 include arsenic (As), phosphorus (P), antimony (Sb), and the like.

The mesa portion of the transistor portion 70 includes the emitter region 12 exposed to the front surface of the semiconductor substrate 10. The emitter region 12 is provided in contact with the gate trench portion 40. The mesa portion in contact with the gate trench portion 40 is provided with the contact region 15 exposed to the front surface of the semiconductor substrate 10.

Each of the contact region 15 and the emitter region 12 in the mesa portion is provided from one trench portion to the other trench portion in the X axis direction. As an example, the contact region 15 and the emitter region 12 in the mesa portion are alternately arranged along the extending direction of the trench portion (the Y axis direction).

In another example, the contact region 15 and the emitter region 12 in the mesa portion may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The emitter region 12 is not provided in the mesa portion of the diode portion 80. An upper surface of the mesa portion of the diode portion 80 may be provided with the base region 14. The base region 14 may be arranged in the entire mesa portion of the diode portion 80. The base region 14 of the diode portion 80 operates as an anode.

The contact hole 54 is provided above each mesa portion. The contact hole 54 is arranged in a region sandwiched between the base regions 14 in its extending direction (Y axis direction). The contact hole 54 of the present example is provided above respective regions of the contact region 15, the base region 14, and the emitter region 12. The contact hole 54 may be arranged at the center of the mesa portion in the array direction (the X axis direction).

In the diode portion 80, a cathode region 82 of an N+ type is provided on the back surface of the semiconductor substrate 10. On the back surface of the semiconductor substrate, a region in which the cathode region 82 is not provided may be provided with a collector region 22 of a P+ type. In FIG. 5, a boundary between the cathode region 82 and the collector region 22 is indicated by a dashed line.

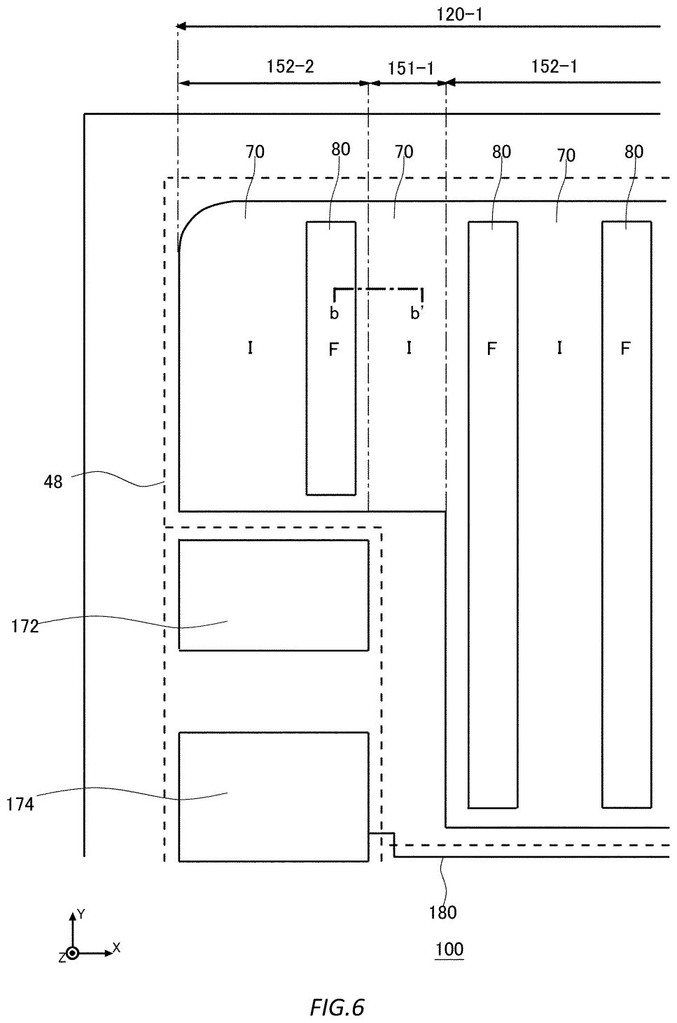

FIG. 6 schematically illustrate a structure of the front surface of the semiconductor substrate 10 in the vicinity of the protected region 151-1. In FIG. 6, the emitter electrode 52 and the like provided above the front surface of the semiconductor substrate 10 are omitted. Note that FIG. 6 illustrates a structure of the active portion 120-1 in the vicinity of the protected region 151-1, and the description of the active portion 120-2 having the similar structure will be omitted. In the diode portion 80, the cathode region 82 is provided on the back surface of the semiconductor substrate 10.

The unprotected region 152-1 is, as described above, provided in the vicinity of the center the active portion 120-1, and the unprotected region 152-2 is provided between the pad region, the protected region 151-1, and the gate metal layer 48 in the positive Y axis direction of the pad region. The unprotected region 152-1 and the unprotected region 152-2 include the transistor portions 70 and the diode portions 80 alternately provided.

Note that FIG. 6 shows each of the unprotected region 152-1 and the unprotected region 152-2 including one transistor portion 70 and one diode portion 80 for simplification, nut they are not limited thereto. Each of the unprotected region 152-1 and the unprotected region 152-2 may include a plurality of transistor portions 70 and diode portions 80 alternately provided.

In the Y axis direction, a length of the unprotected region 152-1 is greater than a length of the unprotected region 152-2. In other words, the unprotected region 152-2 is a region provided in the corner portion of a chip not provided with the unprotected region 152-1 and the pad region. The active portion 120-1 is extended to such a portion so that an area on the chip can effectively utilized.

The protected region 151-1 is interposed between the unprotected region 152-1 and the unprotected region 152-2. The protected region 151-1 of the present example is provided with the transistor portion 70 only, but not provided with the diode portion 80. The protected region 151-1 may be provided in the center portion of the transistor portion 70.

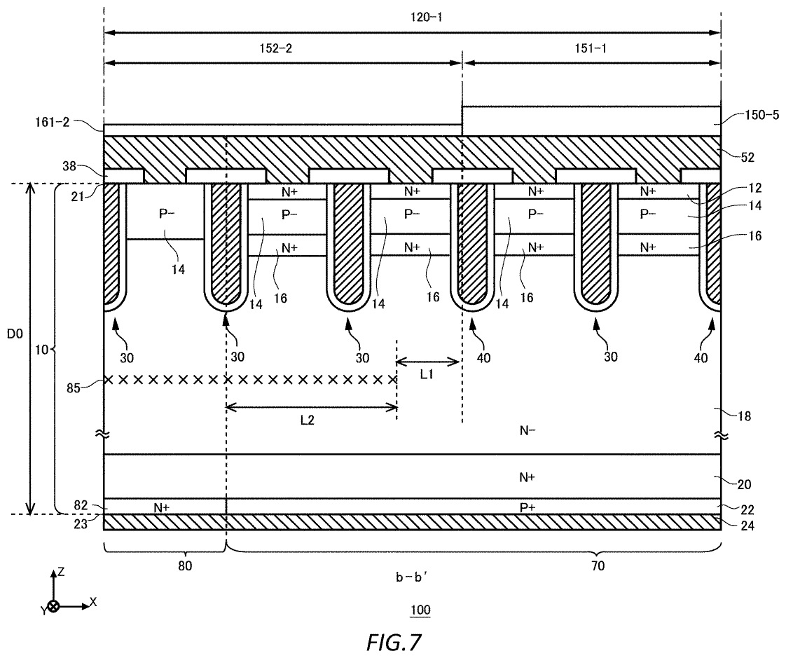

FIG. 7 illustrates an example of a b-b′ cross section of FIG. 6. The b-b′ cross section is an X-Z plane extending through parts of the transistor portion 70 and the diode portion 80 and extending through the emitter region 12 in the transistor portion 70.

The semiconductor device 100 of the present example includes, in the b-b′ cross section, the semiconductor substrate 10, the interlayer dielectric film 38, the emitter electrode 52, the protective film 150-5, the plating portion 161-2 and the collector electrode 24. The interlayer dielectric film 38 is formed above the front surface 21 of the semiconductor substrate 10, and the emitter electrode 52 is formed above the interlayer dielectric film 38.

The drift region 18 is a region provided in the semiconductor substrate 10. The drift region 18 in the present example is of the N-type as an example. The drift region 18 may be a region which has remained without other doping regions formed in the semiconductor substrate 10. That is, a doping concentration in the drift region 18 may be a doping concentration in the semiconductor substrate 10.

The buffer region 20 is a region provided below the drift region 18. The buffer region 20 of the present example is of the same conductivity type as that of the drift region 18, which is an N+ type as an example. The doping concentration of the buffer region 20 is higher than the doping concentration of the drift region 18. The buffer region 20 may function as a field stop layer for preventing a depletion layer, which spreads from the lower surface side of the base region 14, from reaching the collector region 22 and the cathode region 82.

The collector region 22 is a region provided below the buffer region 20 in the transistor portion 70, and is of the conductivity type different from that of the drift region 18. The cathode region 82 is a region provided below the buffer region 20 in the diode portion 80, and is of the same conductivity type as that of the drift region 18. A boundary between the collector region 22 and the cathode region 82 is a boundary between the transistor portion 70 and the diode portion 80.

The collector electrode 24 is formed at the back surface 23 of the semiconductor substrate 10. The collector electrode 24 is formed of a conductive material such as metal.

The base region 14 is a region provided above the drift region 18 in the mesa portion, and having a conductivity type different from that of the drift region 18. The base region 14 of the present example is, for example, of P-type. The base region 14 is provided in contact with the gate trench portion 40. The base region 14 may be provided in contact with the dummy trench portion 30.

The emitter region 12 is provided between the base region 14 and the front surface 21 of the semiconductor substrate 10. The emitter region 12 of the present example is provided in the mesa portion of transistor portion 70, but not provided in the mesa portion of the diode portion 80. The emitter region 12 is provided in contact with the gate trench portion 40. The emitter region 12 may be or may not be in contact with the dummy trench portion 30.

Although not shown in FIG. 6, the contact regions 15 are alternately provided with the emitter regions 12 in the mesa portion of the transistor portion 70. The contact region 15 may be provided to extend to a position deeper than the emitter region 12 in the semiconductor substrate 10.

The accumulation region 16 is a region provided closer to the front surface 21 of the semiconductor substrate 10 than the drift region 18. The accumulation region 16 of the present example is of the same conductivity type as the that of the drift region 18, and is of N+ type, as an example. The accumulation region 16 of the present example is only provided in the transistor portion 70, but may also be provided in the diode portion 80. In addition, the accumulation region 16 may be provided in multiple layers.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. Providing the accumulation region 16 can increase a carrier injection enhancement effect (IE effect) to reduce an ON voltage of the transistor portion 70.

One or more gate trench portions 40 and one or more dummy trench portions 30 are provided in the front surface 21 of the semiconductor substrate 10. Each trench portion is provided from the front surface 21 to the drift region 18 of the semiconductor substrate 10. In a region provided with at least any of the emitter region 12, the base region 14, the contact region 15, and the accumulation region 16, each trench portion also passes through these regions to reach the drift region 18.

Note that the configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

The gate trench portion 40 has a gate trench, a gate dielectric film 42, and a gate conductive portion 44 that are formed in the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21 of the semiconductor substrate 10.

The gate conductive portion 44 includes, in the depth direction of the semiconductor substrate 10 (−Z axis direction), a region opposing to the base region 14 adjacent on the mesa portion side, with the gate dielectric film 42 interposed therebetween. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 includes a dummy trench, a dummy dielectric film 32, and the dummy conductive portion 34 that are formed in the front surface 21 side of the semiconductor substrate 10. The dummy dielectric film 32 is provided to cover an inner wall of the dummy trench. The dummy conductive portion 34 is provided in the dummy trench, and is provided on an inner side further than the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided to a front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may be provided to pass through the interlayer dielectric film 38.

From the diode portion 80 to at least a part of the transistor portion 70, the lifetime control region 85 including a lifetime killer is provided in the drift region 18. The lifetime control region 85 is a crystal defect formed inside the semiconductor substrate 10 by implanting helium ions and the like to a predetermined depth position. The lifetime control region 85 facilitates holes generated in the base regions 14 of the diode portion 80 and the transistor portion 70 and electrons injected from the cathode region 82 to be re-coupled to each other when turning off the diode portion 80 to facilitate carrier elimination, thereby reducing a peak current during reverse recovery.

In FIG. 7, a peak position of the concentration distribution of lifetime killers in the Z axis direction is indicated by a symbol “x”. In the Z axis direction, a peak position of the concentration distribution of lifetime killers may be the same depth as the lower end of the well region 130 or may be deeper. The lifetime control region 85 may also be formed to have a plurality of peaks of the concentration distribution of lifetime killers in the Z axis direction.

The lifetime control region 85 of the present example is formed by irradiating proton or helium from the front surface 21 side of the semiconductor substrate 10. In an example, the lifetime control region 85 is formed by irradiating helium ions while a region where the lifetime control region 85 is not to be formed is covered with a mask such as a resist.

The lifetime control region 85 of the present example is provided only in the unprotected region 152, but not provided in the protected region 151. The lifetime control region 85 is spaced apart from the protected region 151, and a distance L1 between the protected region 151-1 and the lifetime control region 85 in the X axis direction is equal to or greater than 20 μm and equal to or smaller than 1800 μm.

As described above, helium ions are irradiated from the front surface 21 side of the semiconductor substrate 10 to form the lifetime control region 85. However, as a helium ion is a light ion, the projected range is changed in the protected region 151 where the protective film 150 is provided so that the depth direction positions of the lifetime control region 85 vary between the protected region 151 and the unprotected region 152.

Therefore, in the present example, the protected region 151 is not irradiated with helium ions, while only the unprotected region 152 is irradiated with helium ions such that the lifetime control region 85 can have a uniform depth direction position to facilitate carrier elimination when turning off the diode portion 80, thereby reducing a peak current during reverse recovery.

In the X axis direction, a distance L2 by which the lifetime control region 85 extends in the transistor portion 70 is equal to or greater than 80% and equal to or smaller than 250% of a thickness DO of the semiconductor substrate 10. The thickness DO of the semiconductor substrate 10 refers to a distance from the front surface 21 to the back surface 23 in the depth direction (−Z axis direction) of the semiconductor substrate 10. The thickness DO of the semiconductor substrate 10 of the present example may be equal to or greater than 50 μm and equal to or smaller than 150 μm, and may also be equal to or greater than 70 μm and equal to or smaller than 80 μm.

During operation of the diode portion 80, carriers are diffused from the diode portion 80 to the outside. In an example, carriers move from the front surface 21 to the back surface 23 of the semiconductor substrate 10 at an angle of approximately 45 degrees. In the present example, the lifetime control region 85 is provided to extend in the transistor portion 70 by the distance L2 such that carriers diffused from the diode portion 80 can be caught.

In addition, in the X axis direction, a distance between the protected region 151-1 and the diode portion 80 is equal to or greater than the thickness DO of the semiconductor substrate 10. The protective film 150 is formed by over-etching polyimide, which results in a large variance of positions in the finished state. Therefore, a margin is provided to prevent from affecting performance in case of occurrence of a variance.

In this manner, the protected region 151 of the present example is provided inside the transistor portion 70 to be spaced apart from the diode portion 80 and the lifetime control region 85. This can result in the lifetime control region 85 provided without being affected by the protective film 150 to facilitate carrier elimination when turning off the diode portion 80, thereby reducing a peak current during reverse recovery.

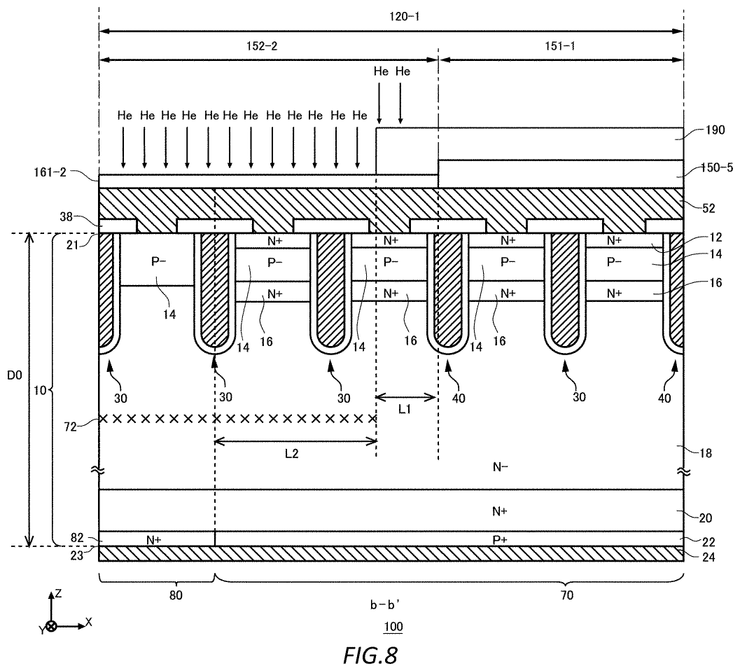

FIG. 8 illustrates an example of a method of fabricating the semiconductor device 100.

Here, in the same manner as FIG. 7 using an example of the b-b′ cross section of FIG. 6, a process of forming the lifetime control region 85 will mainly be described in the method of fabricating the semiconductor device 100.

The method of fabricating the semiconductor device 100 of the present example includes: forming the active portion 120 (the active portion 120-1 in FIG. 8) in which the transistor portions 70 and the diode portions 80 are alternately provided in the semiconductor substrate 10; forming a plurality of trench portions (the gate trench portion 40 and the dummy trench portion 30 in FIG. 8) in the semiconductor substrate 10; and forming the emitter electrode 52 above the front surface 21 of the semiconductor substrate 10.

Forming the active portion 120 includes implanting a dopant into the semiconductor substrate 10 to form impurity implantation regions such as the emitter region 12, the base region 14, the contact region 15, and the accumulation region 16. Forming a plurality of trench portions includes: forming a trench by etching the front surface 21 of the semiconductor substrate 10; forming an insulating film (the gate dielectric film 42 and the dummy dielectric film 32 in FIG. 8) by oxidizing or nitriding a semiconductor of an inner wall of the trench; and forming a conductive portion (the gate conductive portion 44 and the dummy conductive portion 34 in FIG. 8) by filling a space inside the insulating film with a conductive material such as polysilicon. Either of forming the active portion 120 or forming a plurality of trench portions may be performed earlier.

Forming the emitter electrode 52 includes: forming the interlayer dielectric film 38 of BPSG or the like above the front surface 21 of the semiconductor substrate 10; forming a contact hole by etching the interlayer dielectric film 38; and thereafter forming a film of aluminum or an alloy containing aluminum as a main component (for example, an aluminum-silicon alloy, an aluminum-silicon-copper alloy and the like) on the front surface 21 of the semiconductor substrate 10 and the interlayer dielectric film 38.

The method of fabricating the semiconductor device 100 further includes forming the polyimide protective film 150 (the protective film 150-5 in FIG. 8) on an upper surface of the emitter electrode 52. After polyimide applied to the front surface 21 of the semiconductor substrate 10 is spin-coated and cured, the protective film 150 is formed in the protected region 151 (the protected region 151-1 in FIG. 8) by removing polyimide of the unprotected region 152 (the unprotected region 152-2 in FIG. 8.)

In the unprotected region 152, the plating portion 161 (the plating portion 161-2 in FIG. 8) may be formed on the upper surface of the emitter electrode 52. The plating portion 161 of the present example is an Ni/Au film formed by immersion causing an Au film to grow on an Ni film formed by an electroless plating process to prevent oxidization.

The diode portion 80 of the present example is included in the unprotected region 152 and the protected region 151 is included in the transistor portion 70. In the X axis direction, a distance between the diode portion 80 and the protected region 151 is equal to or greater than the thickness DO of the semiconductor substrate 10. The thickness of the semiconductor substrate 10 of the present example may be equal to or greater than 50 μm and equal to or smaller than 150 μm, and may also be equal to or greater than 70 μm and equal to or smaller than 80 μm.

The method of fabricating the semiconductor device 100 further includes forming the lifetime control region 85 in the diode portion 80 by irradiating a lifetime killer from the front surface 21 side of the semiconductor substrate 10. In an example, the lifetime killer is helium or proton.

In the present example, helium ions are irradiated via the resist 190 arranged above the protective film 150. In the X axis direction, a width of the resist 190 is greater than a width of the protective film 150 such that the resist 190 is arranged to cover at least the entire protective film 150 in a top plan view.

In the X axis direction, a distance L1 between an end of the resist 190 and an end of the protective film 150 is equal to or greater than 0 μm and equal to or smaller than 1800 μm. In a top plan view, the end of the resist 190 may be aligned with the end of the lifetime control region 85.

The resist 190 is arranged in the transistor portion 70 to be spaced apart from the diode portion 80. In the X axis direction, a distance between the diode portion 80 and the resist 190 is equal to or greater than 80% and equal to or smaller than 250% of the thickness DO of the semiconductor substrate 10. After the lifetime control region 85 is formed, the resist 190 is removed by a developer.

In this manner, according to a method of fabricating the semiconductor device 100 of the present example, the protected region 151 of the present example is formed inside the transistor portion 70 to be spaced apart from the diode portion 80 and the lifetime control region 85. This can result in the lifetime control region 85 formed without being affected by the protective film 150 to facilitate carrier elimination when turning off the diode portion 80, thereby reducing a peak current during reverse recovery.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate, 12: emitter region, 14: base region, 15: contact region, 16: accumulation region, 18: drift region, 20: buffer region, 21: front surface, 22: collector region, 23: back surface, 24: collector electrode, 25: connecting portion, 29: extending portion, 30: dummy trench portion, 31: connecting portion, 32: dummy dielectric film, 34: dummy conductive portion, 38: interlayer dielectric film, 39: extending portion, 40: gate trench portion, 41: connecting portion, 42: gate dielectric film, 44: gate conductive portion, 48: gate metal layer, 49: contact hole, 50: gate pad, 52: emitter electrode, 54: contact hole, 55: contact hole, 56: contact hole, 70: transistor portion, 80: diode portion, 82: cathode region, 85: lifetime control region, 90: separation portion, 100: semiconductor device, 102: end side, 110: current sensing portion, 120: active portion, 130: well region, 150: protective film, 151: protected region, 152: unprotected region, 153: opening, 154: opening, 161: plating portion, 172: current sensing pad, 174: anode pad, 176: cathode pad, 178: temperature sensing portion, 180: anode wiring, 182: cathode wiring, 190: resist, 210: bidirectional diode portion, 220: output comparison diode portion

What is claimed is:

1. A semiconductor device comprising:
a semiconductor substrate including an active portion in which transistor portions and diode portions are alternately provided and provided with a plurality of trench portions extending in an extending direction of the transistor portion and the diode portion;
an emitter electrode provided above a front surface of the semiconductor substrate; and
a protective film of polyimide provided on an upper surface of the emitter electrode,
wherein the diode portion includes a lifetime control region including a lifetime killer irradiated from a front surface side of the semiconductor substrate,
wherein the active portion includes a protected region provided with the protective film and an unprotected region not provided with the protective film, and
wherein the diode portion is included in the unprotected region and the protected region is included in the transistor portion.

2. The semiconductor device according to claim 1, wherein a width of the transistor portion is equal to or greater than 300 μm and equal to or smaller than 2000 μm in a trench array direction.

3. The semiconductor device according to claim 1, wherein a width of the diode portion is equal to or greater than 200 μm and equal to or smaller than 2000 μm in a trench array direction.

4. The semiconductor device according to claim 1, wherein in a trench array direction, a width of the protected region is equal to or greater than 100 μm and equal to or smaller than 1800 μm.

5. The semiconductor device according to claim 1, wherein in a trench array direction, a distance between the protected region and the diode portion is equal to or greater than a thickness of the semiconductor substrate.

6. The semiconductor device according to claim 1,
wherein in a trench array direction, the lifetime control region is provided to extend from the diode portion to at least a part of the transistor portion, and
wherein in a trench array direction, a distance by which the lifetime control region extends in the transistor portion is equal to or greater than 80% and equal to or smaller than 250% of a thickness of the semiconductor substrate.

7. The semiconductor device according to claim 5 or 6, wherein a thickness of the semiconductor substrate is equal to or greater than 50 μm and equal to or smaller than 150 μm.

8. The semiconductor device according to claim 1,
wherein the lifetime control region is provided only in the unprotected region, and
wherein in a trench array direction, a distance between the protected region and the lifetime control region is equal to or greater than 20 μm and equal to or smaller than 1800 μm.

9. The semiconductor device according to claim 1, further comprising a first plating portion and a second plating portion provided on an upper surface of the emitter electrode, wherein the protective film is interposed therebetween, and
wherein the emitter electrode is provided to extend below the protective film, the first plating portion and the second plating portion.

10. The semiconductor device according to claim 9,
wherein the protective film includes a first protective film and a second protective film between which the first plating portion is interposed, and
thicknesses of the first protective film and the second protective film are greater than a thickness of the first plating portion.

11. The semiconductor device according to claim 1, wherein the unprotected region includes a first unprotected region and a second unprotected region, and the protected region is interposed between the first unprotected region and the second unprotected region.

12. A method of fabricating a semiconductor device, comprising:
forming an active portion in which transistor portions and diode portions are alternately provided in a semiconductor substrate;
forming, in the semiconductor substrate, a plurality of trench portions extending in an extending direction of the transistor portions and the diode portions;
forming an emitter electrode above a front surface of the semiconductor substrate;
forming a protective film of polyimide on an upper surface of the emitter electrode; and
in the diode portion, forming a lifetime control region by irradiating a lifetime killer from a front surface of the semiconductor substrate,
wherein the active portion includes, in a top plan view, a protected region provided with the protective film and an unprotected region not provided with the protective film, and
the diode portion is included in the unprotected region and the protected region is included in the transistor portion.

13. The method of fabricating a semiconductor device according to claim 12,
wherein the lifetime killer is irradiated via a resist arranged above the protective film, and
wherein in a trench array direction, a width of the resist is greater than a width of the protective film.

14. The method of fabricating a semiconductor device according to claim 13, wherein the resist is arranged to at least cover the entire protective film in a top plan view.

15. The method of fabricating a semiconductor device according to claim 14, wherein in a trench array direction, a distance between an end of the resist and an end of the protective film is equal to or greater than 0 μm and equal to or smaller than 1800 μm.

16. The method of fabricating a semiconductor device according to claim 13,
wherein the resist is arranged in the transistor portion to be spaced apart from the diode portion, and
in a trench array direction, a distance between the diode portion and the resist is equal to or greater than 80% and equal to or smaller than 250% of a thickness of the semiconductor substrate.

17. The method of fabricating a semiconductor device according to claim 13, wherein in a trench array direction, a distance between the diode portion and the protected region is equal to or greater than a thickness of the semiconductor substrate.

18. The method of fabricating a semiconductor device according to claim 16, wherein a thickness of the semiconductor substrate is equal to or greater than 50 μm and equal to or smaller than 150 μm.

19. The semiconductor device according to claim 1, wherein the protected region provided in parallel to the extending direction is interposed between the unprotected regions and provided in a center portion of the transistor portion.

20. The method of fabricating a semiconductor device according to claim 12, wherein the protected region provided in parallel to the extending direction is interposed between the unprotected regions and provided in a center portion of the transistor portion.
